(19) United States
(12) Patent Application Publication
(10) Pub. No.: US 2007/0145528 A1
(43) Pub. Date: Jun. 28, 2007

(54) Power dissipation-optimized high-frequency coupling capacitor and rectifier circuit

(75) Inventor: Martin Fischer, Pfedelbach (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/707,996

(22) Filed: Feb. 20, 2007

Related U.S. Application Data
(63) Continuation of application No. PCT/EP05/08853, filed on Aug. 16, 2005.

(30) Foreign Application Priority Data
Aug. 19, 2004 (DE) 10 2004 040 182.9
Jul. 28, 2005 (DE) 10 2005 035 346.0

(51) Int. Cl. H01L 29/00

(52) U.S. Cl. 257/532

(57) ABSTRACT

A power dissipation-optimized high-frequency coupling capacitor is provided for a rectifier circuit as well as a power dissipation-optimized high-frequency rectifier circuit. The elements of the rectifier stages of the inventive high-frequency rectifier circuit are disposed in an optimized manner regarding space such that the coupling capacitors are connected directly to the contact area for the antenna terminal and are arranged around the contact area while taking into account the connecting wires.

This nonprovisional application is a continuation of PCT/EP2005/008853, which was filed on Aug. 16, 2005, which claims priority to German Patent Application Nos. DE 102004040182 and DE 102005035346, which were filed in Germany on Aug. 19, 2004, and Jul. 28, 2005, respectively, and which are all herein incorporated by reference.

### BACKGROUND OF THE INVENTION

1. Field of the Invention

The present invention relates to a power dissipation-optimized high-frequency coupling capacitor for a rectifier circuit, and also to a power dissipation-optimized high-frequency rectifier circuit.

2. Description of the Background Art

Although it is, in principle, applicable to any desired high-frequency rectifier circuit, the present invention and the problem on which it is based are described below with reference to what are known as RFID communications systems and their applications. In this context, RFID stands for “Radio Frequency Identification.” For general background on this technology, please refer to the “RFID Handbuch” by Klaus Finkenzeller, third revised edition, 2002, was has been published in English by John Wiley & Sons.

In RFID communications systems, a high-frequency electromagnetic signal sent out by a base station is received by a transponder. Passive transponders have no energy supply of their own, so they must extract the energy required in the transponder for demodulation and decoding of the received electromagnetic signal from this electromagnetic signal itself. Therefore, in passive RFID systems currently in use, high-frequency signals in the HF and UHF region are transmitted, from which the transponder extracts the energy.

To this end, each transponder has a transmitting and receiving device coupled to the transmitting and receiving antenna. Firstly, this transmitting and receiving device serves to receive and process a received high-frequency data signal. This encompasses both the provision of energy to the transponder and also the demodulation and decoding of the received data signals. In transmit operation, the transmitting and receiving device alters the impedance of the antenna as necessary for the return transmission of data. The structure and function of such a transmitting and receiving device is known in general and has, for example, been described in German patent applications DE 102 56 099 A1, DE 101 58 442 A1, and DE 103 01 451 A1, which corresponds to U.S. Pat. No. 7,151,436, and which are herein incorporated by reference.

In addition to having an antenna, which can be designed as a dipole or inductive antenna, transmitting and receiving devices typically have a voltage source, a rectifier circuit, and a control unit. In this regard, the rectifier is a central and important element of a passive or semipassive transponder for UHF and microwave transmission. A goal in present and future RFID systems is to achieve the greatest possible ranges at the highest possible data transmission rates with passive transponders. A long range can be achieved, in particular, by increasing the transmit power of the base station. However, national and European HF regulations must be observed here, so the transmit power with which the high-frequency electromagnetic signals are transmitted cannot simply be increased to any desired level. In particular, the maximum transmit power is sharply limited with respect to the frequency in question on the basis of these national and European HF regulations. This makes it even more important for the transponder, and especially its transmitting and receiving device, to permit the greatest possible range for the data communication. The efficiency of the rectifier, which thus generates a suitable DC voltage for subsequent circuit components of the transponder from a high-frequency carrier signal, thus plays a very important role which directly affects the reading range of the transponder.

Another aspect of the invention resides in the fact that increasing security requirements for identification in modern RFID systems necessitate ever-higher data rates in order to keep the relevant time periods during which identification can take place as short as possible and thus to transmit a large amount of data modulated on a carrier wave in ever-shorter periods of time. As a result, ever-longer ranges for data communications are required in RFID systems that operate at relatively low power, irrespective of the limited transmit power. In order to meet this requirement, the transponder must extract adequate energy from the electric and/or magnetic fields of the carrier signal even in the case of very weak electric and/or magnetic fields, hence in the far-field region. However, this is only possible when the rectifier of the transponder has a very high efficiency.

For this reason, it is particularly important to design the rectifier of the transmitting and receiving device of the transponder so as to ensure the highest possible efficiency while also meeting all boundary conditions for the data communication. To make the efficiency of the rectifier as high as possible, it is important to minimize the power dissipation within the rectifier, which is primarily caused by parasitic capacitances and resistances. While the power dissipation is negligibly small for low frequency signals, it plays an increasing role for high-frequency signals in particular, for example in the HF and/or UHF frequency regions. The parasitic components of the rectifier, especially the parasitic substrate capacitances and parasitic sheet and series resistances, become increasingly important with increasing carrier signal frequency. These parasitic components result in increasing power dissipation, and thus decreasing rectifier efficiency, with increasing frequency. This is a situation that is to be avoided or at least mitigated.

### SUMMARY OF THE INVENTION

It is therefore an object of the present invention is to provide a rectifier that is optimized with regard to power dissipation for use in a transponder. In accordance with the invention, this object is attained through a high-frequency coupling capacitance for a rectifier circuit and a high-frequency rectifier circuit.

Accordingly, provision is made for an integrated lateral high-frequency coupling capacitor for a rectifier circuit, with a substrate and with at least one capacitance finger in the form of a strip arranged on a front side of the substrate, including at least one electrically conductive cathode layer, which is contacted at the front side through at least one cathode contact strip and has a parasitic series resistance resulting from the ratio of a sheet resistance length to a sheet resistance width within the cathode layer, and at least one electrically conductive anode layer that is insulated from the cathode layer by a dielectric and that is electrically contacted on the front side by at least one anode contact strip, wherein the sheet resistance length identifies the lateral spacing projected in the layout plane between the cathode contact strip and the anode contact strip, wherein the sheet resistance width identifies the lateral length projected in the layout plane within which both the anode layer and the cathode layer are contacted by the anode contact strip and the cathode contact strip with a lateral separation that corresponds to the sheet resistance length, and wherein the sheet resistance length is much smaller than the sheet resistance width.

A multi-stage high-frequency rectifier circuit that is optimized with regard to power dissipation for use in a transponder with an input for coupling in a high-frequency AC signal, having at least one contact area for an antenna connection, with an output for picking up a rectified output signal, with multiple rectifier stages arranged in parallel to one another between the input and the output, each of which stages has a series circuit of a coupling capacitance designed for high-frequency applications, a rectifier diode arranged in the forward direction thereto, and a load capacitance designed for low-frequency applications, wherein the different coupling capacitances are arranged parallel to one another as projected in the layout plane and are each connected directly to the contact area in a space-optimized manner and are arranged around the contact area.

The recognition underlying the present invention is that the efficiency of the rectifier increases as the power dissipation within the rectifier is reduced. This recognition results in the requirement to minimize the parasitic capacitances and parasitic resistances in the rectifier, which are responsible for an unwanted power dissipation. In this regard, the following relationship applies in general to the power dissipation P of a series circuit of, for example, a substrate capacitance C and its series resistance R, the substrate capacitance C and its series resistance R form a voltage divider. The substrate capacitance C here is lossless in and of itself. The power dissipation P is thus equal to the power dissipated in the resistance R. For a given potential U relative to the potential of a substrate or of a well in a semiconductor substrate, the current I through this substrate capacitance C and its series resistance R at a frequency f is given by:

$$I = \frac{U}{\sqrt{( {R}^{2} + 1 / {( 2 π fC )}^{2} )}} . \qquad ( 1 )$$

Accordingly, the power dissipation P is:

$$P = \frac{{I}^{2} R}{2} = \frac{{U}^{2} R}{2 ( {R}^{2} + 1 / {( 2 π fC )}^{2} )} . \qquad ( 2 )$$

For the case in which the quality Q is very high, the following thus applies:
1/(2πfC)>>R. (3)

Hence, the power dissipation P is approximated by:

$$\begin{matrix}P = \frac{1}{2} {{U}^{2} ( 2 π fC )}^{2} R , & ( 4 ) \\ P \approx {C}^{2} R . & ( 5 )\end{matrix}$$

It can be seen from Equation (5) that the substrate capacitance C enters quadratically into the power dissipation P, while the series resistance R is only directly proportional to the power dissipation P. However, the substrate capacitance C of a component is primarily determined by the technology. Thus, for the same function of the component, the underlying technology determines the possibilities for optimization.

A concept underlying the present invention is that the power dissipation of a high-frequency rectifier can be minimized by: a) suitable circuit topology of the individual components of the rectifier; b) appropriate selection of the components. Components that are suitable for a high-frequency rectifier include Schottky diodes as well as capacitors that have low series resistance and thus a high quality factor and the smallest possible parasitic components such as substrate diodes; and/or c) a suitable layout. For a suitable layout, the arrangement of individual components of the high-frequency rectifier is structured such that the parasitic factors resulting from wiring and connecting lines, such as series resistance, substrate diodes, and parasitic capacitance, are minimized.

In an integrated high-frequency coupling capacitor, an anode electrode and cathode electrode are each made up of semiconductor layers, for example highly doped polysilicon or highly doped monocrystalline silicon. In the case of a high-frequency coupling capacitor of lateral design, the relevant semiconductor layers for the anode and cathode are each contacted from the same side, for example from the front side of a semiconductor body (semiconductor substrate). Anode and cathode contact strips, respectively, are provided for contacting. To ensure a defined contact between this anode contact strip or cathode contact strip and the corresponding anode layer or cathode layer, it is advantageous for the anode contact strip or cathode contact strip to contact the relevant anode layer or cathode layer more or less over a large area. In the case of a lateral implementation of the high-frequency coupling capacitor, the anode contact strips have a lateral separation relative to the cathode contact strips so that the least possible parasitic capacitance is produced between the anode contact strips and cathode contact strips, and also so that no undesired short circuit is present between these contact strips.

A high-frequency coupling capacitor such as is described above typically has two integrated series resistances. In the case of the anode, the resistance results from the thickness of the anode layer, since charge carriers in the anode layer move essentially vertically between the anode contact strip and the dielectric. In addition, another parasitic series resistance is present which results from the effective, or in other words average, distance that a charge carrier must travel in the cathode layer. This distance typically results from the sheet resistance length, which is defined by the lateral distance projected in the layout plane between the cathode contact strip and the anode contact strip.

In order to keep the parasitic series resistances as low as possible in accordance with the above discussion, both the series resistance in the anode layer and the series resistance in the cathode layer must be minimized. The series resistance in the anode zone can be minimized in a very simple manner by a very thin anode layer. In this case, the series resistance in the anode zone is negligible (especially in comparison to the series resistance in the cathode zone). This is typically not the case for the series resistance in the cathode layer. This is due, firstly, to the fact that the anode layer arranged on the cathode layer, and in particular the corresponding dielectric, have a certain lateral extent that is at least significantly larger than the thickness of the anode layer. Secondly, the cathode strip must have a certain separation from the anode strip and/or the anode layer to allow for defined contacting and also to prevent parasitic interaction (for example, a parasitic capacitance) with the anode contact strip and/or the anode layer. Since the high-frequency coupling capacitor must have a capacitance specified by the application, it is also not possible to select the lateral extent of the anode layer to be arbitrarily narrow. For this reason, the sheet resistance length, which is directly proportional to the series resistance of the cathode layer, cannot be neglected.

The sheet resistance width should be selected to be very large, and in particular sufficiently large that the sheet resistance length is very much smaller than the sheet resistance width. In this regard, the ratio of sheet resistance length to sheet resistance width largely determines the magnitude of the series resistance in the cathode layer. Since the ratio of sheet resistance length to sheet resistance width becomes smaller as the sheet resistance width is selected to be larger, the series resistance in the cathode layer can be minimized accordingly in this way. In this manner, in spite of a predetermined design and a predetermined defined application, or in other words a predetermined value for the high-frequency coupling capacitor, its series resistance can be reduced to a minimum, especially in the cathode layer. It is true that this is done at the cost of a greater lateral extent of the high-frequency coupling capacitor. However, this enlargement of the chip area is tolerable because of the better electrical properties, in particular with regard to power dissipation, which are produced as a result.

High-frequency coupling capacitors can be used in multi-stage high-frequency power dissipation-optimized rectifier circuits, such as are used in transponders. In this context, each one of these stages has a series circuit of a coupling capacitance designed for high-frequency applications, a rectifier diode arranged in the forward direction thereto, and a load capacitance designed for low-frequency applications. The insight here is that the connecting lines between these elements and to the external connections play a major role in determining the power dissipation. The connections that are connected directly to the antenna are especially serious in this regard, since the frequency of the received signal coupled in through the antenna is the highest there, which directly contributes to the power dissipation. The concept is for the coupling capacitance, which is designed for high-frequency applications and which is connected at its input side to the antenna, to be directly adjacent to the contact area for the antenna connection. Since a plurality of such coupling capacitances are present, each of which is associated with one of the rectifier stages, the various coupling capacitances are arranged parallel to one another and are connected directly to the contact area and around the contact area. In this context, “directly” means that while each of the coupling capacitances is by nature connected to the contact area through connecting lines, this connecting line has a minimal length. “Minimal” in this context means that the design rules dictated by the technology must be followed, i.e., the connecting lines must each maintain a spacing from adjacent connecting lines that is determined by the technology. Thus, as a whole, the result is a very compact, space-optimized arrangement of the coupling capacitances within the multi-stage rectifier circuit.

In an embodiment, the ratio of sheet resistance length to sheet resistance width can be in a range of ½ to 1/1000. The ratio of sheet resistance length to sheet resistance width can be in the range of 1/10 to 1/100.

In another embodiment, the anode contact strips and the cathode contact strips are arranged parallel to one another (at least in sections). In this regard, the respective parallel sections of the anode contact strips and the cathode contact strips have a minimal separation from one another. In this context, “parallel” refers to the respective longitudinal orientation of the anode contact strips and the cathode contact strips. The anode layer can also be designed as an elongated layer whose longitudinal orientation is parallel to the anode contact strip arranged thereon and to the cathode contact strip.

The anode contact strip can contact the anode layer, and/or the cathode contact strip contacts the cathode layer (along the sheet resistance width), via a plurality of contact holes that are arranged very close together. The use of a plurality of contact holes arranged very close together for making contact is especially advantageous, particularly for high-frequency applications, since it minimizes parasitic effects (resistances) which could result from a single local contacting.

Instead of using contact holes for contacting the anode contact strip and cathode contact strip, a large-area electrical contact to these strips on the anode layer or the cathode layer would also be possible. However, it has been demonstrated that contacting by contact holes arranged very close together allows a defined electrical contact. “Contact holes arranged very close together” can be interpreted, in an example, to mean that no continuous contact strip is present for contacting the corresponding anode layer or cathode contact layer. However, this results in almost no difference in the semiconductor layer in comparison with a large-area contact, since the charge carriers in the anode layer or the cathode layer largely distribute themselves in such a manner that contacting by contact holes has an effect that is almost identical to an optimal contacting by a continuous contact strip. What is important in this regard is that the contact holes are arranged sufficiently close together to result in a largely homogeneous distribution of charge carriers in the relevant semiconductor layers.

In an embodiment, the cathode layer can be contacted on both sides with respect to the anode layer (at least in sections) by cathode contact strips. This reduces the sheet resistance of this cathode layer and the series resistance by at least a factor of two.

In another embodiment, the anode contact strips can be arranged centrally within the anode layer in such a manner that the anode contact strips have, as far as possible, equal separation from the lateral edges of the anode layer. They preferably have a minimal separation in this regard. In the same manner, the cathode contact strips have a minimal separation from the lateral edges of the anode layer. Here and throughout the entire patent application, “minimal” means that a minimal separation is chosen while taking into account the design rules dictated by the technology.

In yet another embodiment, a plurality of capacitance fingers can be provided that are arranged parallel to one another and, in particular, with a minimal spacing from one another. This permits a compact construction and thus a compact design. This is advantageous for very large capacitances.

The substrate is typically embodied as a highly doped semiconductor substrate that is electrically contacted through substrate contact strips. However, any other substrate, for example a circuit board, a thin film or the like, can be used as the substrate. In the latter case, i.e. the case of a substrate embodied as a circuit board, film, or the like, an integrated coupling capacitor is still involved, since its components, i.e. its anode and cathode, are embodied in integrated form as a semiconductor anode layer and semiconductor cathode layer.

The substrate contact strips can have a minimal separation from the lateral edges of the cathode layer.

In an embodiment, the anode contact strips and/or the cathode contact strips can contain metal or a metallic alloy. Preferably, a material that has very good conductivity is used here, i.e. one that is designed with the lowest possible resistance and thus provides no parasitic ohmic contributions. The anode layer and/or the cathode layer typically has a highly doped polysilicon. Any other conductive material with as low a resistance as possible would also be conceivable here. However, the production of the polysilicon layers is very simple and inexpensive in terms of manufacturing technology and is thus preferred.

In an embodiment, adjacent coupling capacitances have an equal separation from one another in the projection of the layout plane, and in particular a minimal separation.

In an embodiment, the anode layer can also have an additional parasitic series resistance resulting essentially from the vertical separation between the anode contact strip and the dielectric within the anode layer. Preferably, the additional parasitic series resistance in the anode layer is very much smaller than the parasitic series resistance in the cathode layer. The additional parasitic series resistance is typically smaller than the parasitic series resistance in the cathode layer by at least a factor of 10, preferably by at least a factor of 100, and typically by a factor of at least 1000.

In another embodiment, at least one additional diode is arranged between at least two adjacent rectifier stages, connecting the anode of the rectifier diodes of one rectifier stage to the cathode of the rectifier diodes of the adjacent rectifier stage. In this way, the rectifier circuit is at the same time developed into a voltage multiplier circuit, providing a further improvement in the efficiency of the rectifier circuit.

In another embodiment, the rectifier diodes, taking their connecting lines into account, are connected directly to the coupling capacitances associated therewith. In addition, it is advantageous for the additional diodes, taking their connecting lines into account, to be connected directly to the respective diodes of the respective adjacent rectifier stages to which they are connected. All of this, which is to say the direct connection and thus the optimization or shortening of the connecting lines, reduces the losses and increases the efficiency of the rectifier.

The rectifier diodes and/or the additional diodes are preferably embodied as Schottky diodes. Of course, conventional diode types are also possible, but the losses would be higher. Of course, the use of transistors and/or transistors connected in diode circuits would also be possible. Schottky diodes have a higher efficiency than standard diodes and are thus preferred.

In another embodiment, a load capacitance of a relevant rectifier stage is connected directly, taking its connecting line into account, to a connection of the rectifier diode associated with this load capacitance. All of this, which is to say the direct connection and thus the optimization or shortening of the connecting lines, reduces the losses and increases the efficiency of the rectifier.

In an embodiment, a reference potential ring can have a reference potential, which is arranged directly around the entire arrangement of the rectifier stages and connects all reference potential nodes of the rectifier stages to the reference potential with low resistance. This ensures a uniform voltage reference for all elements of the rectifier.

At least one guard ring can be provided that is arranged directly around the entire arrangement of the rectifier stages. This guard ring protects the elements of the rectifier stages from parasitic overvoltage pulses coupled in from outside the rectifier. Overall, this results in improved EMC protection.

In this embodiment, it is also advantageous for at least some and preferably all elements of the rectifier stages (with the exception of the Schottky diodes in the case where Schottky diodes are used), and preferably also the contact area for the antenna connection, to be embedded in a well in the semiconductor substrate, the well being provided specifically for this purpose and advantageously being very highly doped and thus low-resistance. In this way, the rectifier circuit is designed as an integrated rectifier circuit.

Further, the rectifier circuit can have at least one coupling capacitance.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic diagram of a five-stage high-frequency rectifier;

FIG. 2 is a layout of the high-frequency rectifier from FIG. 1;

FIG. 3 is a cross-section through a capacitance finger of a coupling capacitance having optimized power dissipation from the rectifier in FIG. 2;

FIG. 4. is a layout of a coupling capacitance having optimized power dissipation.

### DETAILED DESCRIPTION

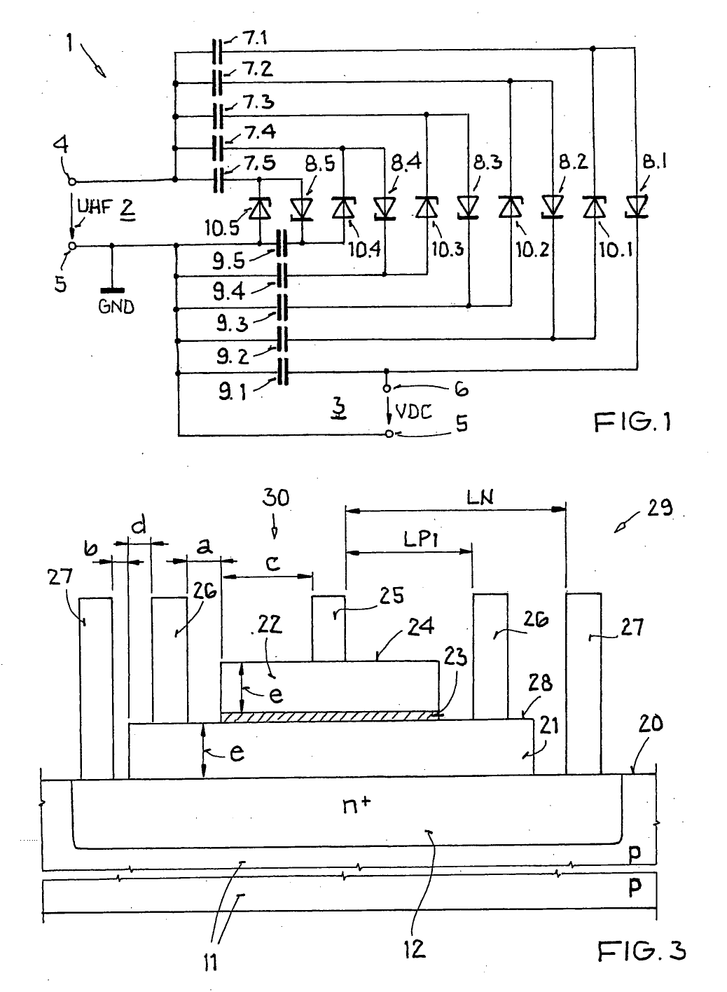

FIG. 1 shows a schematic diagram of a five-stage high-frequency rectifier. The rectifier here is labeled with reference number 1. The rectifier 1 has an input 2 and an output 3. Provided at the input 2 are a first connection 4, for example an antenna pad or antenna connection, and a second connection 5. In the present example embodiment, the second connection 5 has the potential of the reference ground GND. In operation of the rectifier 1, a high-frequency electromagnetic AC signal VHF is coupled in through the input 2 and through the antenna pad 4, so that a high-frequency AC voltage UHF drops across the connections 4, 5. The output 3 has a first output connection 6 and a second output connection 5 that is likewise connected to the potential of the reference ground GND. Thus, an output signal VDC, which is represented as a more or less rectified DC signal VDC, can be obtained between the output connections 6, 5.

The rectifier 1 has a multi-stage design as shown in FIG. 1, and in the example shown has a total of five rectifier stages. In the present example embodiment, each rectifier stage contains a coupling capacitance 7.1-7.5, a diode 8.1-8.5 arranged in the forward direction thereto and embodied as a Schottky diode, and an additional Schottky diode 10.1-10.5, and a load capacitance 9.1-9.5. The coupling capacitances 7.1-7.5, Schottky diodes 8.1-8.5 and load capacitances 9.1-9.5 of each rectifier stage are connected in series with one another, wherein the coupling capacitance 7.1-7.5 is arranged in the high-frequency section and the load capacitance is arranged in the low-frequency section of each respective rectifier stage, and wherein the high-frequency section and low-frequency section are isolated by the Schottky diode 8.1-8.5.

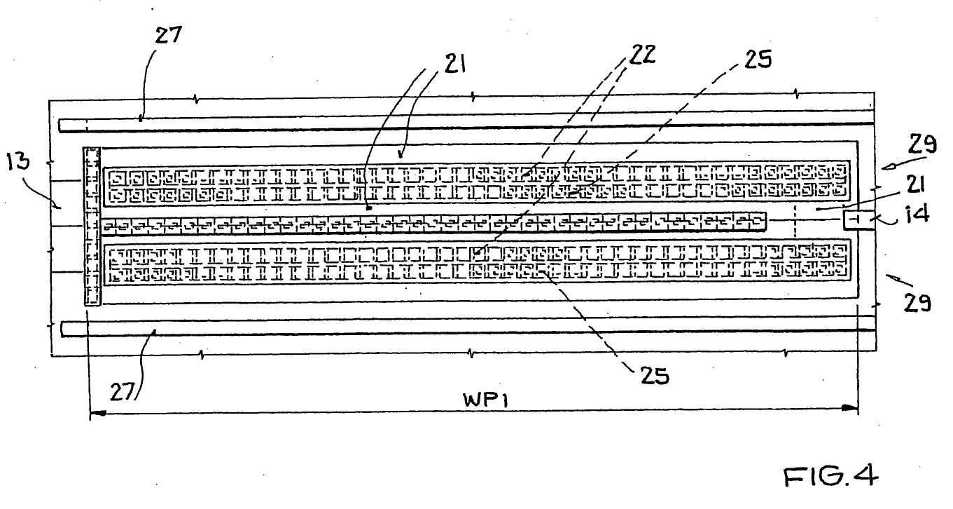

The coupling capacitances 7.1-7.5 and/or the load capacitances 9.1-9.5 are typically designed as capacitors, and in particular as integrated capacitors. The precise structure of such an integrated coupling capacitor 7.1-7.5 is described in detail below on the basis of FIGS. 3 and 4.

The coupling capacitances 7.1-7.5 serve to couple in the high-frequency signal VHF. The coupling capacitances 7.1-7.5 have a typical capacitance value of approximately 100 fF-1000 fF. The actual rectification is accomplished by means of the Schottky diodes 8.1-8.5, 10.1.-10.5, with the Schottky diodes 8.1.-8.5 being provided for the positive half-cycles of the coupled-in signal and the Schottky diodes 10.1.-10.5 being provided for the negative half-cycles. The load capacitances 9.1-9.5 serve to accumulate the coupled-in signal and provide a DC voltage VDC at the output 3 of the rectifier 1. The parasitic elements (substrate) are connected to ground and short-circuited and are thus ineffective. The load capacitances 9.1-9.5 are thus in a region of the rectifier 1 that is noncritical with regard to high frequencies, and have a typical capacitance value of approximately 0.5-10 pF.

The anodes of the additional Schottky diodes 10.1-10.5 are connected to the cathodes of the respective Schottky diodes 8.1-8.5 of the one rectifier stage, and the cathodes of the additional Schottky diodes 10.1-10.5 are connected to the anodes of the respective Schottky diodes 8.1-8.5 of the other adjacent rectifier stage, so that overall, a series circuit of three Schottky diodes from respective adjacent rectifier stages is formed as a result. As a result, the potential present on the output side at the Schottky diodes 8.1-8.5 of the one rectifier stage is essentially coupled-up as it is provided to the adjacent Schottky diodes 8.1-8.5. By this means, the rectifier 1 has the functionality of a voltage multiplier circuit, in which the voltage signal at the output 3 has a higher voltage value than at the input 2. In particular, by means of the circuit topology shown in FIG. 1, for a coupled-in AC signal VHF at the input in the range of approximately 350 mV, a DC voltage of approximately 1.2 V can be achieved at the output. Overall, the rectifier 1 thus has a very high efficiency through suitable wiring of the individual components of the rectifier 1, since the voltage amplitude of the DC voltage signal VDC provided at the output is greater by approximately a factor of 3 than that of the AC signal UHF at the input.

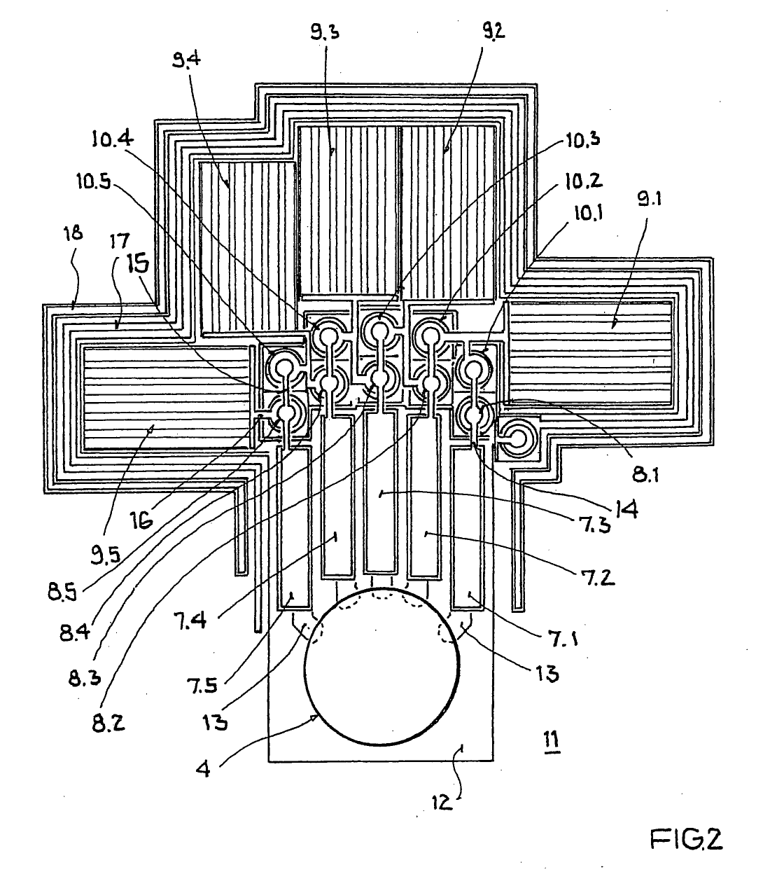

FIG. 2 shows the layout of the five-stage rectifier from FIG. 1. Here, the complete rectifier arrangement is arranged in a semiconductor substrate 11 in an integrated fashion. Provided in the semiconductor substrate 11 is an n-doped well 12 in which all elements of the rectifier circuit 1 except the Schottky diodes 8.1-8.5, 10.1-10.5 are located. The Schottky diodes 8.1-8.5, 10.1-10.5 require a separate n-doped well. An essentially circular antenna pad 4 is provided in this well 12. In this way, the high-frequency electromagnetic signals VHF can be coupled into the rectifier 1 through this antenna pad 4, which can for example be connected by a connecting line, which is not shown, to an antenna of a transponder, which likewise is not shown. Here and throughout the entire patent application, an antenna pad 4 designates a more or less large contact area for an antenna connection.

In addition, five coupling capacitances 7.1-7.5 are provided which are directly connected to the antenna pad 4 by respective connecting lines 13. In this context, “direct” means that the connecting lines 13 are designed to be as short as possible, where the length of the connecting lines 13 depends solely on the technology and thus on the design rules on which it is based. In like manner, the spacings of adjacent connecting lines 13 and coupling capacitances 7.1-7.5 depend primarily on the design rules, which must be observed for reasons of the technology.

The coupling capacitances are—as described below in detail using FIGS. 3 and 4—fingerlike in design and arranged as close as possible to the antenna pad 4. In this context, “as close as possible” means that there is a minimal distance between the coupling capacitances 7.1-7.5 and the antenna pad 4. The connecting lines 13 are also as short as possible in consideration of the technologies used, and meet the minimum distance between antenna pad 4 and coupling capacities 7.1-7.5. Moreover, the coupling capacitances 7.1-7.5 are arranged parallel to one another and as close together as possible in the well 12 in a space-saving manner. In this way, a very compact arrangement is achieved of the coupling capacitances 7.1-7.5 with respect to one another and with respect to the antenna pad 4.

Directly on the right at the coupling capacitances 7.1-7.5 on the output side, a corresponding Schottky diode 8.1-8.5 is connected to each coupling capacitance 7.1-7.5. Directly adjoining these Schottky diodes 8.1-8.5 are Schottky diodes 10.1-10.5, with a very space-saving layout being present in the connections of the Schottky diodes 8.1-8.5, 10.1-10.5 to one another as well as in their connections to the coupling capacitances 7.1-7.5. To this end, the individual Schottky diodes 8.1-8.5, 10.1-10.5 border directly on one another in order to keep the lengths of the connecting lines 14, 15 between them and to the adjacent coupling capacitances 7.1-7.5 as small as possible while preserving the technology-dictated minimum spacings specified by the design rules in developing the layout.

The Schottky diodes 8.1-8.5, 10.1-10.5, which are arranged in a very tight and compact manner relative to one another, are connected to the load capacitances 9.1-9.5 by connecting lines 16. Here, the load capacitance 9.1 and the load capacitance 9.5 are arranged vertical and perpendicular to the orientation of the coupling capacitances 7.1-7.5, while the remaining load capacitances 9.2-9.4 have the same orientation as the coupling capacitances 7.1-7.5. The load capacitances 9.1-9.5 are also arranged as close as possible to the respective Schottky diodes 8.1-8.5 while maintaining the minimum spacings.

The layout shown in FIG. 2 has proven to be especially advantageous, particularly for a UHF application, and also offers a very compact, space-saving and thus economical layout variant. Of course, it would also be conceivable for all load capacitances 9.1-9.5 to be arranged in the same orientation to one another or also to the capacitances 7.1-7.5. However, in that case the requirement for the greatest possible compactness of the layout might no longer be met.

Thus, the overall result for the rectifier arrangement, which is embedded in the n-doped well 12, is a layout that is compact and essentially cruciform in a top view. Arranged at least partially around this well 12 is a continuous strip-shaped layer 17 to which the reference potential GND is applied. This layer thus constitutes what is known as the ground ring 17, which represents a low-resistance voltage reference for the voltage signals of the rectifier 1. This ground ring 17 is in turn to be located as close as possible to the n-doped well 12 while observing the variations and minimum spacings dictated by the technology. In addition, a guard ring 18 is arranged around this ground ring 17. This guard ring 18 is also to be located as close as possible to the ground ring 17 and the rectifier 1 while observing the minimum spacings. This guard ring 18 is used for electromagnetic compatibility and is intended to keep out undesirable interfering signals that might possibly be coupled into the rectifier circuit 1 from outside.

It must be noted in the layout in FIG. 2 that the individual connecting lines 13-16 are to be understood as merely connections among the elements of the rectifier circuit 1, and for this reason are to be kept as short as possible in order to minimize undesired parasitic influences resulting from these connecting lines 13-16. It goes without saying that although it would be desirable, it is not possible to reduce these connecting lines 13-16 and their lengths to zero, since it is necessary to maintain technologically dictated minimum spacings, specified by design rules, between the individual elements of the rectifier circuit 1.

In the top view of the layout, the coupling capacitances 7.1-7.5 and load capacitances 9.1-9.5 are finger-shaped in design. Such a coupling capacitance 7.1-7.5 or load capacitance 9.1-9.5 has an approximately rectangular shape in this regard and contains one or preferably multiple capacitance fingers, which are arranged parallel to one another within the rectangular structure of the relevant capacitance 7.1-7.5, 9.1-9.5 and which typically have the same orientation as the relevant capacitance 7.1-7.5, 9.1-9.5.

FIG. 3 shows a cross section through an individual capacitance finger 29 of an inventive coupling capacitance having optimized power dissipation of the high-frequency rectifier in FIG. 2.

Embedded in the semiconductor substrate 11, for example a weakly p-doped or undoped silicon substrate, is an n-doped well 12. A thin, first polysilicon layer 21 is applied to a surface 20 of the n-doped well 12. The first polysilicon layer 21 is applied more or less centrally on the n-doped well 12. Arranged over the first polysilicon layer 21 is a thin, second polysilicon layer 22, wherein the second polysilicon layer 22 is insulated and separated from the first polysilicon layer 21 by a thin dielectric 23, for example silicon dioxide or silicon nitride. The second polysilicon layer 22 is also arranged on the first polysilicon layer 21 centrally with respect thereto.

Likewise centrally applied to a surface 24 of the second polysilicon layer 22 is an anode metallization 25. This anode metallization 25 advantageously has an equal spacing c from the left and right edges of the second polysilicon layer 22. Cathode metallizations 26 are also applied laterally spaced from the first polysilicon layer 21 and on a free surface 28 of the first polysilicon layer 21. These cathode metallizations 26 are preferably arranged on both sides with respect to the second polysilicon layer 22, and also typically have an equal spacing a therefrom. In like manner, the substrate metallizations 27 are applied to the first surface 20 of the well 12, and are preferably arranged on both sides with respect to the first polysilicon layer 21 and laterally spaced therefrom.

FIG. 3 shows a cross-section that is not to scale. The layer thicknesses e of the first and/or second polysilicon layers 21, 22 are in the nanometer range, typically in the range of 100-300 nm, preferably approximately 300 nm. LP1 designates the length of a sheet resistance in the cathode layer 21, which designates the spacing projected in the layout between the anode metallizations 25 and the cathode metallizations 26. In like manner, LN designates the length of the well 12 which designates the spacing between the anode metallization 25 and the substrate metallization 27 in the production of the layout. Typical values for the length LP1 lie in the range from 1-3 μm, and 4-5 μm for the length LN.

The coupling capacitance has two series resistances, with the first series resistance arising from the sheet resistance in the cathode layer 21, and thus from the length LP1. The second series resistance arises from the sheet thickness e of the anode layer 22. Since the sheet thickness e of the anode layer 22 is vanishingly small in comparison with the length LP1 of the cathode layer 21, the series resistance in the anode layer 22 can be neglected in comparison with the series resistance in the cathode layer 21.

The spacings a between the cathode metallization 26 and the lateral edges of the second polysilicon layer 22, and also the spacings b between the substrate metallization 27 and the lateral edges of the first polysilicon layer 21, should preferably be kept as small as possible. These spacings a, b are typically determined by technology-dictated minimum spacings specified by the design rules. In like manner, the spacings c between the anode metallization 25 and the lateral edges of the corresponding second polysilicon layer 22, and also the spacings d between the cathode metallization 26 and the lateral edges of the corresponding first polysilicon layer 21, should also be kept as small as possible and are likewise typically derived from the design rules. The spacings between adjacent substrate metallizations 27 and cathode metallizations 26, and between cathode metallizations 26 and anode metallizations 25, should also be made as small as possible so that no parasitic capacitive effects arise from these metallizations 25-27.

The anode metallizations 25, cathode metallizations 26, and substrate metallizations 27 are typically designed as contact rows. In practice, such contact rows are designed as continuous contact layers or contact paths, which contact the relevant semiconductor substrate or the relevant polysilicon layer. In this way a point contact, where the relevant semiconductor substrate or the relevant polysilicon layer is only contacted at a single point, is prevented in that multiple contacts over a large area are made with the relevant polysilicon layer 21, 22 or the semiconductor body 11, 12 over a long distance. This is particularly advantageous, especially for high-frequency applications, since it is ensured here that the high-frequency electromagnetic signal is simultaneously coupled into or picked up from the relevant layer at multiple points, which measure prevents or at least largely minimizes undesirable parasitic effects such as sheet resistance, parasitic capacitances, etc. On the whole, the use of contact rows having a plurality of contact holes to the substrate to be contacted, said holes being arranged very close together, permits very low-resistance contacting.

In the present example embodiment, it is assumed that the n-doped well 12 has a very high dopant concentration of, e.g., 10¹⁶-10¹⁹ cm⁻³. A high dopant concentration of the n-doped well 12 is especially advantageous, particularly with regard to reducing the substrate resistance of the well 12. The polysilicon layers 21, 22 are typically designed to be the most highly doped layers possible in order to keep the influence of their sheet resistance, and thus the associated power dissipation, as small as possible. However, instead of using doped polysilicon here, any other conductive material can be used for these layers 21, 22, such as a metallic layer, a metal alloy, or the like, for example. However, polysilicon is best suited here on account of its good processing characteristics, since the corresponding capacitive elements can be produced most economically in this way. A metallic layer, for example aluminum, copper, or the like, is preferably used as the material for the contacts.

FIG. 4 shows the layout of a single coupling capacitance having optimized power dissipation. In contrast to the cross-section from FIG. 3, the second polysilicon layer 22 is doubled here, in other words, two capacitance fingers 29 are provided within the coupling capacitance. Since the middle cathode metallization 26 is used here for both laterally adjacent polysilicon layers 22, this coupling capacitance has a very space-saving, compact form when two or more capacitance fingers 29 are used within one coupling capacitance.

The width WP1 of the sheet resistance in the cathode layer results essentially from the lengths of the first and second polysilicon layers 21, 22 here. This is due to the fact that the anode metallization 25 and cathode metallization 26 contact the respective polysilicon layers 21, 22 of the anode layer 22 and cathode layer 21 over nearly their entire longitudinal extent. In the example in FIGS. 3 and 4, the width WP1, and thus the width of the sheet resistance, designates the lateral length, projected in the layout plane, within which both the anode layer 22 and the cathode layer 21 are contacted at a lateral spacing LP1 by the respective anode metallizations and cathode metallizations (parallel to one another). This approximate relationship applies in particular to all cases where the anode layer 22 is made very thin and where it can thus be assumed as an approximation that the area of the anode layer 22 contacted by anode metallizations 25 (anode contact strips 25) likewise corresponds to the effective dielectric for the coupling capacitor. As the thickness e of the anode layer 22 increases, however, this approximate relationship increasingly fails to apply. Hence, it is in general the case that the width WP1 of the sheet resistance in the cathode layer 21 is determined by the effective width of the active capacitor dielectric under the anode metallization 21. In like manner, it is in general the case that the sheet resistance length LP1 is determined by the lateral spacing between the outer edges of the effective active capacitor dielectric and the corresponding cathode metallization 26 (cathode contact strip 26). The width WP1 is typically between 50-500 μm.

The functional principle of a suitably chosen layout (FIG. 2) of the rectifier and the suitable selection and design of the components, in particular the coupling capacitances, of the rectifier (FIGS. 3 and 4), and their advantages, are described below.

Minimizing parasitics through appropriate selection of individual components:

Since, as mentioned above in conjunction with the coupling and load capacitances, the substrate capacitance can only be minimized to a limited extent because it is dependent on the technology, the selection of a suitable layout centers on minimizing its series resistance Rs and substrate resistance Rsub. The series resistance Rs of these capacitances comprises primarily of the resistance in the first polysilicon layer 21, i.e. in the cathode layer, which can be calculated as follows:

$$Rs = 0.5 \cdot \frac{LP 1}{WP 1} \cdot rP 1 , \qquad ( 6 )$$

where LP1 designates the effective length of the first polysilicon layer 21 (with respect to the distance traveled by the charge carriers in the cathode layer 21), WP1 designates the effective width of the first polysilicon layer 21, and rP1 designates the sheet resistance of the first polysilicon layer 21 (see FIGS. 2 and 3).

It can be seen from Equation (6) that the series resistance Rs can be minimized if LP1 is chosen to be minimal and WP1 is chosen according to the desired capacitance value. The factor 0.5 results from the fact that the first polysilicon layer 21 is contacted from both sides of this polysilicon layer 21, resulting in two resistances of equal size arranged in parallel with one another. The minimum length LP1 is specified by the minimum spacing of the anode contacts 25 from the second polysilicon layer 22, hence by the applicable design rules of the technology employed. Since the anode contacts 25 also typically have an ohmic component which thus contributes to the series resistance, it is advantageous, in the case of a small capacitance value and a correspondingly small number of possible contact holes in this contact row 25, to provide not just one contact row 25—as is shown in FIG. 3—but multiple anode contact rows 25 arranged parallel to one another within a capacitance finger 29. In this way the total number of contact holes is increased, and since the anode contact rows 25 are parallel to one another, the contribution of the anode contacts 25 to the total resistance is reduced.

An embodiment uses not just one capacitance finger 29, but multiple contact fingers 29 parallel to one another for a correspondingly large capacitance, since with a very long capacitance finger 29 the ohmic contribution of the anode contact strip, which connects the different anode contact holes together, can become disproportionately large. Consequently, it is typical and also preferred to choose multiple shorter capacitance fingers 29 arranged parallel to one another, as shown in FIG. 4, for example, wherein the coupling capacitance has two capacitance fingers 29.

The substrate resistance Rsub can be reduced by placing, beneath the first polysilicon layer 21 (FIG. 3), a relatively low-resistance i.e. relatively heavily n-doped well 12 and connecting it to the reference potential GND and thus the ground ring 17 by means of many substrate contacts 27 (FIG. 4). The substrate resistance Rsub is calculated as follows:

$$Rsub = 0.5 \cdot \frac{LN}{WP 1} \cdot rN , \qquad ( 7 )$$

where LN designates the length of the n-doped well 12, WP1 the width of the well 12, which is approximately equal in size to the corresponding width of the polysilicon layer 21, and rN designates the sheet resistance of the well 12 (see FIGS. 3 and 4).

It can be seen from Equation (7) that the substrate resistance Rsub is minimized by selecting the length LN to be minimal. Since the width WP1 is very much greater than the length LN for normal capacitance values, a relatively low substrate resistance Rsub is achieved in this way.

Once again, the factor 0.5 here results from the fact that the well 12 is contacted from both sides, resulting in two resistances of equal size arranged in parallel with one another. The well 12 is preferably contacted on all sides, so that in this case a factor even lower than 0.5 results.

Minimizing parasitics through appropriate layout of the rectifier:

The coupling capacitances 7.1-7.5 (see FIG. 2) should be arranged as close as possible around the antenna pad 4, by which means the length of the lines 13 between the antenna pad 4 and the coupling capacitances 7.1-7.5 and thus their line capacitances and series resistances can be minimized. A saving in the chip area of the rectifier also results. If the AC voltage value U is known, then a width WP1 for these lines that is optimized with regard to power dissipation can be determined with the aid of the foregoing equations. Since this AC voltage value U is at its maximum before and after the respective coupling capacitances 7.1-7.5, and thus the power dissipation, into which the voltage enters quadratically according to Equation (4), is especially high, it is especially important to avoid parasitic elements in these places. This is also the reason why the two associated Schottky diodes 8.1-8.5, 10.1-10.5 (see FIGS. 1 and 2) are placed immediately after or directly adjacent following each coupling capacitance 7.1-7.5. This arrangement of the Schottky diodes 8.1-8.5, 10.1-10.5 serves to further minimize the line parasitics.

At the nodes between the Schottky diodes 8.1-8.5, 10.1-10.5 and the load capacitances 9.1-9.5 (FIGS. 1 and 2), the AC voltage value U is smaller, and thus the power dissipation by parasitic elements is far smaller. Nevertheless, these elements should not be neglected here either, for which reason the load capacitances 9.1-9.5 are preferably placed in direct connection to the Schottky diodes 8.1-8.5, 10.1-10.5 in the layout (FIGS. 1 and 2). A ground ring 17 is placed around the entire rectifier circuit 1, providing all nodes of the rectifier circuit that are connected to the potential GND of the reference ground with a low-resistance connection to the antenna ground GND (see FIG. 1) and thus minimizing the parasitic series resistance.

Moreover, in order to minimize parasitic elements, it is useful to place circuits and/or components that are directly connected to the antenna pad as close to one another around the antenna pad 4 as possible—insofar as the available space permits this—since the AC voltage value U has its maximum directly at the antenna pad 4, and the influence of parasitic elements has the most serious effect with regard to power dissipation (see Equation (4)) there.

Although the present invention is described above using a preferred example embodiment, it is not limited thereto, but rather can be modified in a variety of ways.

Thus, the invention is described above on the basis of a five-stage rectifier. It is self-evident that the rectifier can also have more or fewer rectifier stages, or can be designed as only a single stage. Moreover, the dimensioning of the individual elements of the rectifier, including in particular the capacitance values, doping concentrations, lengths, widths and spacings, have been specified solely for the purpose of better understanding, and do not in any case limit the invention in that regard. It is self-evident that an arbitrarily large number of different layout variants and circuit variants can be obtained by interchanging the n and p conductivity types and vice versa, without departing from the scope of the invention. The same applies to replacing the individual elements of the rectifier with differently designed but functionally equivalent elements. Of course, instead of using only one coupling capacitor and/or Schottky diode and/or load capacitance per rectifier stage, provision can also be made to provide several of these elements per rectifier stage.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated lateral high-frequency coupling capacitor for a rectifier circuit having a substrate and at least one capacitance finger in the form of a strip arranged on a front side of the substrate, the coupling capacitor comprising:
at least one electrically conductive cathode layer that is contacted at a front side through at least one cathode contact strip and has a parasitic series resistance resulting from a ratio of a sheet resistance length to a sheet resistance width within the cathode layer; and
at least one electrically conductive anode layer that is insulated from the cathode layer by a dielectric and that is electrically contacted on the front side by at least one anode contact strip,
wherein the sheet resistance length identifies a lateral spacing projected in a layout plane between the cathode contact strip and the anode contact strip,
wherein the sheet resistance width identifies a lateral length projected in the layout plane within which the anode layer and the cathode layer are contacted by the anode contact strip or the cathode contact strip, respectively, with a lateral separation that corresponds to the sheet resistance length, and
wherein the sheet resistance length is smaller than the sheet resistance width.

2. The coupling capacitor according to claim 1, wherein the ratio of sheet resistance length to sheet resistance width is in a range of ½ to 1/1000 or in a range of 1/10 to 1/100.

3. The coupling capacitor according to claim 1, wherein the anode contact strips and the cathode contact strips are arranged parallel to one another, at least in sections.

4. The coupling capacitor according to claim 1, wherein the anode contact strip contacts the anode layer and/or the cathode contact strip contacts the cathode layer by a plurality of contact holes that are arranged close together.

5. The coupling capacitor according to claim 1, wherein the cathode layer is contacted on both sides, with respect to the anode layer, by cathode contact strips.

6. The coupling capacitor according to claim 1, wherein the anode contact strips are arranged centrally within the anode layer so that the anode contact strips have a substantially equal lateral separation from edges of the anode layer, in particular a minimal lateral separation.

7. The coupling capacitor according to claim 6 wherein the cathode contact strips have a minimal lateral separation from the edges of the anode layer.

8. The coupling capacitor according to claim 1, wherein a plurality of capacitance fingers are provided that are arranged substantially parallel to one another with a minimal lateral spacing from one another.

9. The coupling capacitor according to claim 1, wherein the substrate is a highly doped semiconductor substrate that is electrically contacted through substrate contact strips.

10. The coupling capacitor according to claim 9, wherein the substrate contact strips have a minimal lateral separation from the edges of the cathode layer.

11. The coupling capacitor according to claim 1, wherein the anode contact strips and/or the cathode contact strips contain metal and/or a metallic alloy.

12. The coupling capacitor according to claim 1, wherein the anode layer and/or the cathode layer have highly doped polysilicon.

13. The coupling capacitor according to claim 25, wherein the additional parasitic series resistance in the anode layer is smaller than the series resistance in the cathode layer by at least a factor of 10.

14. A multi-stage power dissipation-optimized high-frequency rectifier circuit for use in a transponder, comprising:
an input for coupling in a high-frequency AC signal having at least one contact area for an antenna connection;
an output for receiving a rectified output signal; and
multiple rectifier stages arranged in parallel to one another between the input and the output, each of the rectifier stages comprising:
a series circuit of a coupling capacitance for high-frequency applications;
a rectifier diode arranged in a forward direction; and
a load capacitance for low-frequency applications,
wherein the coupling capacitances are arranged parallel to one another in a projection of the layout plane and are each connected directly to a contact area for the antenna connection and are arranged around the contact area.

15. The rectifier circuit according to claim 14, wherein adjacent coupling capacitances have an equal lateral separation from one another in the projection of the layout plane, and in particular a minimal lateral separation.

16. The rectifier circuit according to claim 14, wherein the rectifier diodes are connected directly to the coupling capacitances associated with the rectifier diodes.

17. The rectifier circuit according to claim 14, wherein at least one additional diode is arranged between at least two adjacent rectifier stages, connecting the anode of the rectifier diodes of one rectifier stage to the cathode of the rectifier diodes of the respective adjacent rectifier stage.

18. The rectifier circuit according to claim 17, wherein the additional diodes are connected directly to the respective rectifier diodes of the respective adjacent rectifier stages to which they are connected.

19. The rectifier circuit according to claim 14, wherein the rectifier diodes and/or the additional diodes are Schottky diodes.

20. The rectifier circuit according to claim 14, wherein a load capacitance of a relevant rectifier stage is connected directly to a connection of the rectifier diode associated with this load capacitance.

21. The rectifier circuit according to claim 14, further comprising a reference potential ring having a reference potential, the reference potential ring being arranged directly around the entire arrangement of the rectifier stages and connects all reference potential nodes of the rectifier stages to the reference potential.

22. The rectifier circuit according to claim 14, further comprising at least one guard that is arranged directly around the entire arrangement of the rectifier stages.

23. The rectifier circuit according to claim 14, wherein the elements of the rectifier stages and the contact area for the antenna connection are designed in integrated form and are embedded in a well in a semiconductor substrate.

24. The rectifier circuit according to claim 14, wherein at least one of the coupling capacitances is an integrated coupling capacitor according to claim 1.

25. The coupling capacitor according to claim 1, wherein the anode layer includes an additional parasitic series resistance that results from a vertical distance of the anode contact strip to the dielectric, and wherein the parasitic series resistance in the anode layer is substantially smaller than the series resistance in the cathode layer.

26. A transponder comprising a rectifier circuit according to claim 1.
